(19) United States
(12) Patent Application Publication
(10) Pub. No.: US 2009/0101994 A1
(43) Pub. Date: Apr. 23, 2009

(54) SEMICONDUCTOR DEVICE AND METHOD FOR FABRICATING THE SAME

(76) Inventor: Kyoung-Mi Moon, Daiseong-gun (KR)

Correspondence Address: SHERR & VAUGHN, PLLC, 620 HERNDON PARKWAY, SUITE 200, HERNDON, VA, 20170, US

(21) Appl. No.: 12/246,669

(22) Filed: Oct. 7, 2008

(30) Foreign Application Priority Data
Oct. 19, 2007 (KR) 10-2007-0105445

(51) Int. Cl. H01L 47/00; H01L 29/00; H01L 21/20

(52) U.S. Cl. 257/412; 257/536; 438/382; 257/E29.001; 257/E21.09; 257/E47.001

(57) ABSTRACT

A semiconductor device and a method for fabricating the same are disclosed. The semiconductor device includes a semiconductor substrate having an active region and a device isolation region defining the active region, and a resistor string formed over the active region.

The present application claims priority under 35 U.S.C. §119 to Korean Patent Application No. 10-2007-0105445 (filed on Oct. 19, 2007), which is hereby incorporated by reference in its entirety.

### BACKGROUND

Generally, liquid crystal displays are adapted to display an image as a light transmittance of dielectric anisotropic liquid crystals are adjusted using an electric field. For this, such a liquid crystal display includes a liquid crystal display panel in which liquid crystal cells are arranged in a matrix, and a driving circuit to drive the liquid crystal display panel. The liquid crystal display panel displays an image as the light transmittance of liquid crystal cells is adjusted according to pixel signals. The driving circuit includes a gate driver to drive gate lines of the liquid crystal display panel, a data driver to drive data lines, a timing controller to apply timing control signals and pixel data to both the gate driver and the data driver, and a power source to supply a power voltage. The data driver and the gate driver of the liquid crystal display are fabricated in a chip form in which a plurality of discrete integrated circuits is integrated. Each integrated LCD driver IC (LDI) is mounted on and/or over the liquid crystal display panel in a tape automated bonding (TAB) manner or in a chip-on-glass (COG) manner.

A plurality of LDI chips have different characteristics and therefore, a block dim phenomenon causing a differential gray level occurs on a display panel. The block dim phenomenon is caused by an output voltage difference of resistor string blocks within an LDI. In turn, such an output voltage difference of the resistor string blocks is caused because controlling a critical dimension (CD) of a gate conductive film and a silicide anti-block (SAB) layer is becoming difficult due to a thickness deviation of a field oxide film and a dishing phenomenon.

### SUMMARY

Embodiments relate to a semiconductor device and a method for fabricating the same that prevents a block dim phenomenon caused by a liquid crystal display (LCD) driver integrated circuit (IC) (LDI).

Embodiments relate to a semiconductor device that may include at least one of the following: a semiconductor substrate having an active region and a device isolation region defining the active region; and a resistor string formed on and/or over the active region. In accordance with embodiments, the resistor string may include at least one of the following: a gate insulating film formed on and/or over the semiconductor substrate; a gate conductive film formed on and/or over the gate insulating film over the active region; a silicide pattern formed on and/or over a partial region of the gate conductive film; an interlayer insulating film covering the silicide pattern and the gate conductive film; and a metal pattern layer disposed on and/or over the interlayer insulating film and forming a contact with the silicide pattern. In accordance with embodiments, the gate insulating film may be a high-voltage gate insulating film and the interlayer insulating film may be made of one of phosphorus silicate glass (PSG) and boron phosphorus silicate glass (BPSG).

Embodiments relate to an apparatus that may include at least one of the following: a semiconductor substrate having an active region; a gate insulating film formed over the semiconductor substrate in the active region; a gate conductive film formed over the gate insulating film in the active region; a silicide pattern formed over the gate conductive film in the active region; an interlayer insulating film formed over and contacting the silicide pattern, the gate conductive film and the gate insulating film; a plurality of contact holes formed extending through the interlayer insulating film to expose a plurality of portions of the uppermost surface of each one of the silicide patterns; and a metal pattern layer having a first portion formed over the interlayer insulating film and second portions filling the contact holes to contact the silicide pattern.

Embodiments relate to a method for fabricating a semiconductor device that may include at least one of the following steps: providing a semiconductor substrate having an active region and a device isolation region defining the active region; and then forming a gate insulating film on and/or over the semiconductor substrate; and then forming a gate conductive film on and/or over the gate insulating film over the active region; and then forming a photoresist pattern on and/or over the gate conductive film; and then forming a silicide pattern on and/or over the gate conductive film in empty spaces of the photoresist pattern; and then removing the photoresist pattern; and then forming an interlayer insulating film covering the silicide pattern and the gate conductive film; and then forming a contact hole in the interlayer insulating film to expose the silicide pattern; and then forming a metal pattern layer forming a contact with the silicide pattern.

Embodiments relate to a method for fabricating a semiconductor device that may include at least one of the following steps: defining an active region in a semiconductor substrate; and then forming a gate insulating film in the active region; and then forming a gate conductive film over the gate insulating film in the active region; and then forming photoresist patterns spaced apart over the gate conductive film; and then forming a silicide pattern over the gate conductive film in the spaces between the photoresist patterns; and then removing the photoresist pattern; and then forming an interlayer insulating film over the silicide pattern and the gate conductive film; and then forming contact holes in the interlayer insulating film to expose portions of the silicide pattern; and then forming a metal pattern layer over the interlayer insulating film and filling the contact holes to contact the exposed portions of the silicide pattern.

### DRAWINGS

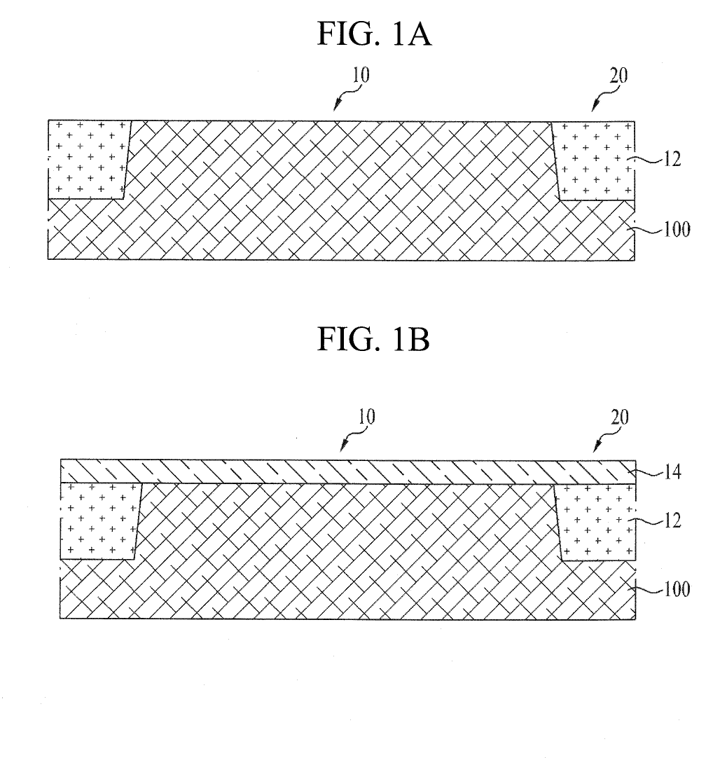

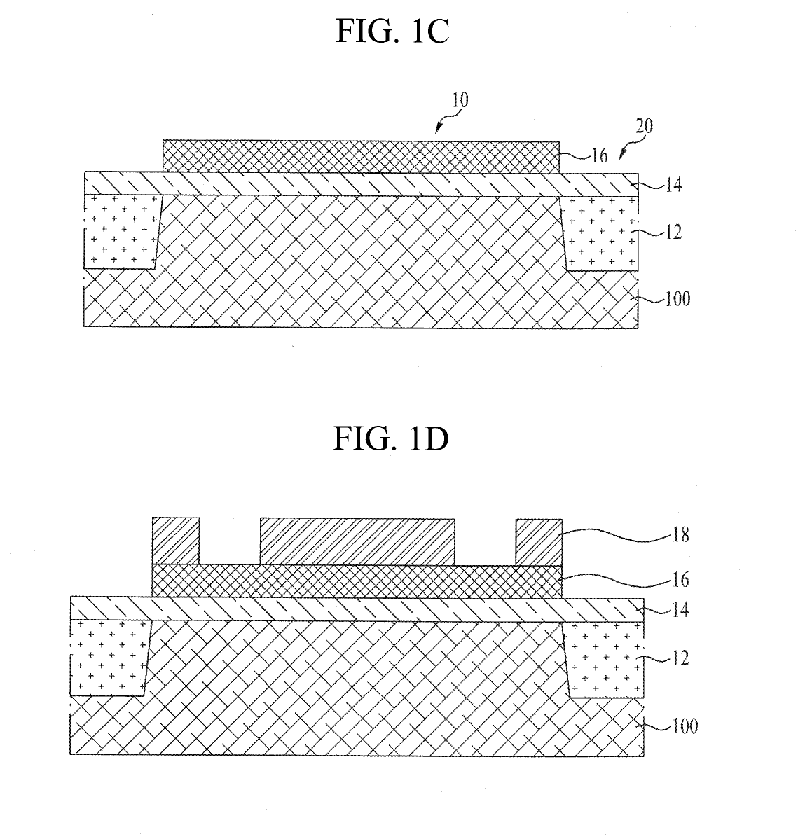

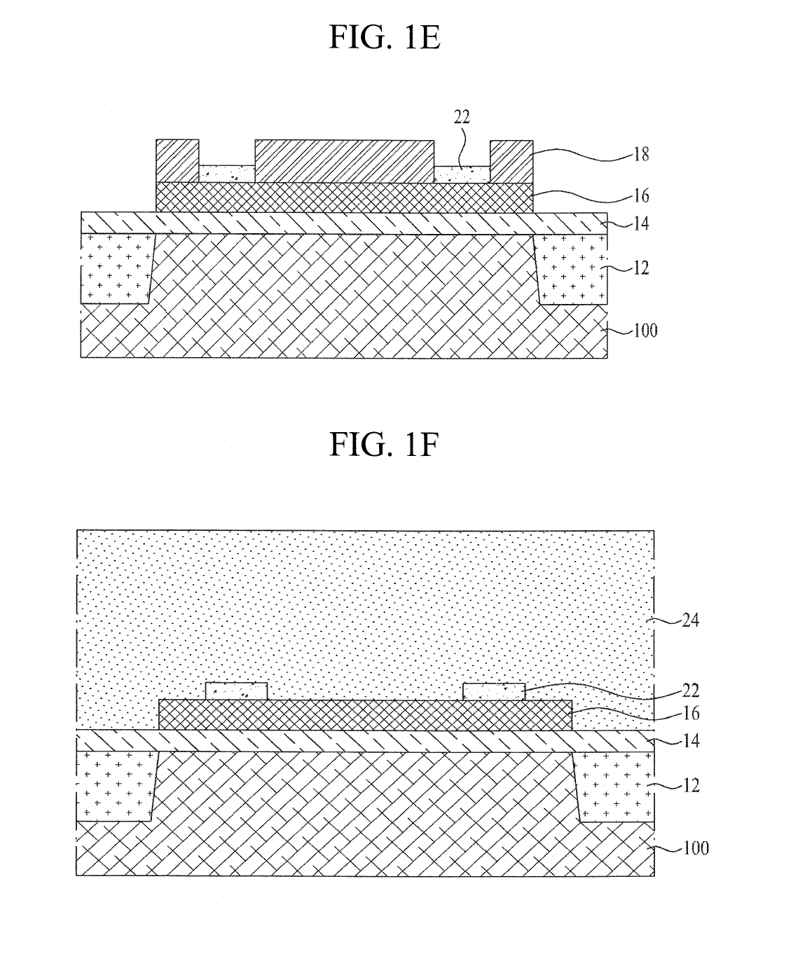

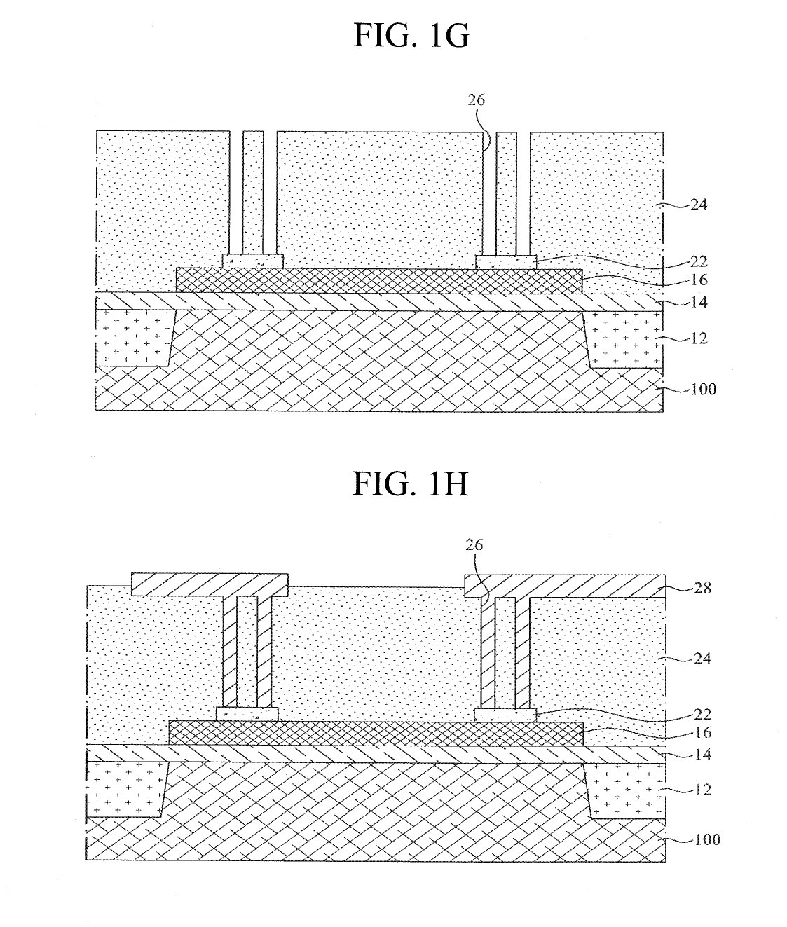

Example FIGS. 1A to 1H illustrate a method for fabricating a semiconductor device in accordance with embodiments.

### DESCRIPTION

Reference will now be made in detail to embodiments, examples of which are illustrated in the accompanying drawings. Wherever possible, the same reference numbers will be used throughout the drawings to refer to the same or like parts.

As illustrated in example FIG. 1A, in accordance with embodiments, semiconductor substrate 100 is provided having active region 10 and device isolation region 20 defining active region 10. In the semiconductor device in accordance with embodiments, a resistor string is formed in active region 10. Device isolation film 12 may be formed by sequentially forming a pad oxide film, a pad nitride film, and a tetra ethyl ortho silicate (TEOS) oxide film on and/or over semiconductor substrate 100. A photosensitive film is then formed on and/or over the TEOS oxide film. Next, the photosensitive film is patterned via exposure and developing processes using a mask to thereby form device isolation region 20 defining active region 10. Through this patterning, the photosensitive film in device isolation region 20 is removed. Then, portions of the pad oxide film, the pad nitride film, and the TEOS oxide film of device isolation region 20 are selectively removed using the patterned photosensitive film as a mask.

Subsequently, semiconductor substrate 100 in device isolation region 20 is etched to a predetermined depth using the patterned pad oxide film, the pad nitride film and the TEOS oxide film as etching masks, thereby forming trenches in substrate 100. After completion of the etching, the overall photosensitive film is removed. A sacrificial film composed of an oxide material is then formed thinly on and/or over an entire surface of substrate 100 including the trenches. The sacrificial film may be formed by depositing an O₃-TEOS film on and/or over substrate 100 and filling the trenches. The sacrifice film is formed on inner walls of the trenches. Formation of the O₃-TEOS film serving as the sacrificial oxide film may be performed at a temperature of approximately 1,000° C. or more. Thereafter, the entire surface of semiconductor substrate 100 is subjected to a chemical mechanical polishing (CMP) process to remove a portion of the O₃-TEOS film except for the portion of the O₃-TEOS film filling the trenches. Thereby, device isolation film 12 is formed in the trenches. Then, the remaining portions of the pad oxide film, the pad nitride film and the TEOS film are removed.

As illustrated in example FIG. 1B, after performing a cleaning process on the overall structure of semiconductor substrate 100, gate insulating film 14 is formed on and/or over semiconductor substrate 100 including device isolation film 12. If a bias voltage is applied to the resistor string in active region 10, it may cause breakdown of gate insulating film 14. Therefore, gate insulating film 14 is preferably a high-voltage gate oxide film having a thickness in a range between approximately 200 Å to 300 Å or more.

As illustrated in example FIG. 1C, gate conductive film 16 is formed on and/or over gate insulating film 14 in active region 10. Gate conductive film 16 may be composed of any one of poly-silicon, tungsten (W), tungsten nitride (WN), tungsten silicide (WSiₓ) and combinations thereof.

As illustrated in example FIG. 1D, after coating an entire surface of gate conductive film 16 with a photoresist, the photoresist is patterned via exposure and developing processes, thereby forming a plurality of photoresist patterns 18 formed spaced apart on and/or over gate conductive film 16. Photoresist patterns 18 are provided to form a subsequent silicide pattern.

As illustrated in example FIG. 1E, silicide pattern 22 is formed on and/or over gate conductive film 16 in the spaces between photoresist patterns 18. Specifically, silicide pattern 22 may be formed by depositing a metal material on and/or over gate conductive film 16 and then performing an annealing process on the deposited metal material. The metal material for use in the formation of silicide pattern 22 may be a silicidable material that enables formation of a silicide layer via a reaction with gate conductive film 16. The metal material may be any one of titanium (Ti), tantalum (Ta), nickel (Ni) and cobalt (Co).

As illustrated in example FIG. 1F, photoresist patterns 18 are removed and interlayer insulating film 24 is formed on and/or over gate conductive film 16, silicide pattern 22 and gate insulating film 14. Interlayer insulating film 24 is formed to cover gate conductive film 16 and silicide pattern 22. Interlayer insulating film 24 may be composed of one of phosphorus silicate glass (PSG) and boron phosphorus silicate glass (BPSG).

As illustrated in example FIG. 1G, interlayer insulating film 24 is selectively etched using photolithographic process to form a plurality of contact holes 26 extending through interlayer insulating film 24 to expose portions of silicide pattern 22. Interlayer insulating film 24 may be selectively etched to form a pair of contact holes 26 extending through interlayer insulating film 24 to expose two areas and/or portions of silicide pattern 22.

As illustrated in example FIG. 1H, a metal film is then formed on and/or over interlayer insulating film 24 and filling contact holes 26. A resistor string taking the form of metal pattern layer 28 is formed by patterning the metal film such that metal pattern layer 28 directly contacts silicide pattern 22 at the two areas and/or regions exposed by contact holes 26. A voltage of the resistor string is output via metal pattern layer 28 coming into contact with the silicide pattern 22. The resistor string, formed on and/or over active region 10, has a flatter surface as compared to the case where it is formed on and/or over a device isolation region. Therefore, enhanced control of a deviation in critical dimension (CD) is achieved. Consequently, a reduction in deviation in output voltage of LDIs results, thereby preventing a block dim phenomenon.

As apparent from the above description, a semiconductor device and a method for fabricating the same in accordance with embodiments can reduce deviation in the critical dimension (CD) of a gate conductive film and an SAB, whereby occurrence of a block dim phenomenon due to a deviation in output voltage of LDIs can be prevented.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a semiconductor substrate having a device isolation region defining an active region; and
a resistor string formed over the active region.

2. The semiconductor device of claim 1, wherein the resistor string comprises:
a gate insulating film formed over the semiconductor substrate;
a gate conductive film formed over the gate insulating film in the active region;
a silicide pattern formed over a portion of the gate conductive film;
an interlayer insulating film formed over the silicide pattern and the gate conductive film; and
a metal pattern layer formed over the interlayer insulating film and contacting the silicide pattern.

3. The semiconductor device of claim 2, wherein the gate insulating film comprises a high-voltage gate insulating film.

4. The semiconductor device of claim 2, wherein the interlayer insulating film comprises one of phosphorus silicate glass (PSG) and boron phosphorus silicate glass (BPSG).

5. The semiconductor device of claim 2, wherein the gate insulating film has a thickness in a range between approximately 200 Å to 300 Å.

6. The semiconductor device of claim 2, wherein the gate conductive film comprises at least one of poly-silicon, tungsten (W), tungsten nitride (WN), tungsten silicide (WSiₓ) and combinations thereof.

7. The semiconductor device of claim 2, wherein the silicide pattern comprises at least one of titanium (Ti), tantalum (Ta), nickel (Ni) and cobalt (Co).

8. The semiconductor device of claim 2, further comprising:
a pair of contact holes extending through the interlayer insulating layer exposing portions of the silicide pattern, wherein the metal pattern layer is formed in the contact holes.

9. The semiconductor device of claim 2, wherein a voltage of the resistor string is output via the metal pattern layer coming into contact with the silicide pattern.

10. A method for fabricating a semiconductor device comprising:
defining an active region in a semiconductor substrate; and then
forming a gate insulating film in the active region; and then
forming a gate conductive film over the gate insulating film in the active region; and then
forming photoresist patterns spaced apart over the gate conductive film; and then
forming a silicide pattern over the gate conductive film in the spaces between the photoresist patterns; and then
removing the photoresist pattern; and then
forming an interlayer insulating film over the silicide pattern and the gate conductive film; and then
forming contact holes in the interlayer insulating film to expose portions of the silicide pattern; and then
forming a metal pattern layer over the interlayer insulating film and filling the contact holes to contact the exposed portions of the silicide pattern.

11. The method of claim 10, wherein the gate insulating film comprises a high-voltage gate insulating film.

12. The method of claim 10, wherein the interlayer insulating film comprises one of phosphorus silicate glass (PSG) and boron phosphorus silicate glass (BPSG).

13. The method of claim 10, wherein the gate insulating film has a thickness in a range between approximately 200 Å to 300 Å.

14. The method of claim 10, wherein the gate conductive film comprises at least one of poly-silicon, tungsten (W), tungsten nitride (WN), tungsten silicide (WSiₓ) and combinations thereof.

15. The method of claim 10, wherein the silicide pattern comprises at least one of titanium (Ti), tantalum (Ta), nickel (Ni) and cobalt (Co).

16. An apparatus comprising:
a semiconductor substrate having an active region;
a gate insulating film formed over the semiconductor substrate in the active region;
a gate conductive film formed over the gate insulating film in the active region;
a silicide pattern formed over the gate conductive film in the active region;
an interlayer insulating film formed over and contacting the silicide pattern, the gate conductive film and the gate insulating film;
a plurality of contact holes formed extending through the interlayer insulating film to expose a plurality of portions of the uppermost surface of each one of the silicide patterns; and
a metal pattern layer formed over the interlayer insulating film and also filling the contact holes to contact the exposed portions of the silicide pattern.

17. The apparatus of claim 16, wherein the gate insulating film comprises a high-voltage gate insulating film.

18. The apparatus of claim 16, wherein the gate insulating film has a thickness in a range between approximately 200 Å to 300 Å.

19. The apparatus of claim 10, wherein the gate conductive film comprises at least one of poly-silicon, tungsten (W), tungsten nitride (WN), tungsten silicide (WSiₓ) and combinations thereof.

20. The apparatus of claim 16, wherein the silicide pattern comprises at least one of titanium (Ti), tantalum (Ta), nickel (Ni) and cobalt (Co).
